(19) United States
(12) Patent Application Publication
(10) Pub. No.: US 2003/0075451 A1
(43) Pub. Date: Apr. 24, 2003

(54) Semiconductor integrated circuit, manufacturing method thereof, and manufacturing apparatus thereof

(76) Inventor: Makoto Kanda, Fukuyama-shi (JP)

Correspondence Address: NIXON & VANDERHYE P.C., 8th Floor, 1100 North Glebe Road, Arlington, VA, 22201, US

(21) Appl. No.: 10/247,825

(22) Filed: Sep. 20, 2002

(30) Foreign Application Priority Data
Sep. 25, 2001 (JP) 2001-292278

(51) Int. Cl. C25D 7/12; C25D 11/32; C25D 17/00; H01L 21/44

(52) U.S. Cl. 205/157; 438/678; 204/222

(57) ABSTRACT

A manufacturing apparatus of a semiconductor integrated circuit, having an anode electrode which is provided in a tank section for storing a plating liquid, and a cathode electrode for connecting to a target plating surface of a wafer, further includes induction coils and a high-frequency power source. The manufacturing apparatus of a semiconductor integrated circuit can produce the magnetic field caused by the induction coils and electromagnetic force caused by the current passing through the target plating surface of the wafer, so as to form a bump electrode on the wafer by electrolytic plating method while vibrating the wafer through the electromagnetic force.

### FIELD OF THE INVENTION

The present invention relates to a semiconductor integrated circuit having a bump electrode, a manufacturing method thereof, and a manufacturing apparatus thereof.

### BACKGROUND OF THE INVENTION

In resent years, a high-density mounting of semiconductor devices has been advanced in all fields, particularly in fields of a mobile telephone and a PDA (Personal Data Assistant), of the electronic information industry.

For realization of the high-density mounting, it is necessary to connect a fine electrode pad provided on a semiconductor element (semiconductor device) with a wiring provided on a substrate for mounting the electrode pad (a mounting substrate) so as to be stable electrically and physically. As one method for such a connection, known has been a method of utilizing a bump electrode of gold (Au) provided at an electrode pad section. In mounting a semiconductor integrated circuit having the bump electrode on the mounting substrate, it is essential to make the bump electrode uniform in height for strengthening its connection and securing reliability.

Usually, the above bump electrode on the semiconductor device is formed by a plating method. The plating method is mainly categorized into two methods: “non-electrolytic plating method” and “electrolytic plating method”.

First, the non-electrolytic plating method is a method of depositing a plating metal on a base metal as a target plating substance with a function of a reducing agent, without passing a current through metallic ions in a plating liquid. This method has an advantage that equipments such as a power source (plating power source) are not needed because it uses no current. However, the method has disadvantages of limitation of combination between the base metal and the plating liquid, and of a slow speed in plating growth. For these reasons, the method is unfavorable for formation of a plating layer having a thickness from ten and several μm to several tens of μm, which is a thickness demanded for formation of the bump electrode of the semiconductor device.

On the other hand, the electrolytic plating method is a method of carrying out plating electrochemically by passing a current through a base metal as an electrode immersed into a plating liquid (by ion transport in electrochemical double layers as a region of electrochemical reaction (a transition region)).

This method allows plating to the base metal to which the non-electrolytic plating method cannot carry out plating. Also, the electrolytic plating method is much higher in speed of plating growth, and can form a plating layer having a thickness of several tens of μm more easily, as compared with the non-electrolytic plating method. Therefore, the electrolytic plating method is a favorable method for formation of the bump electrode to the semiconductor device.

The following will outline a method of forming a bump electrode by the electrolytic plating method. A base metallic film, serving as a current film for applying a current (a film passing a current), is adhered on an insulating film provided on a semiconductor substrate (hereinafter referred to as “wafer”) on which a semiconductor device is integrated.

Next, a resist is applied on the foregoing base metallic film, and further, openings are provided at predetermined positions of a photo-resist film, that is, at positions where a bump electrode should be formed, to expose the base metallic film by the photolithography method. A wafer surface is immersed into a plating liquid, and voltage is applied between the base metallic film and a positive electrode (anode electrode), which is provided separately, so as to pass a current (a plating current). Then, a plating metal is deposited in opening sections of the photo-resist film to form the bump electrode.

Incidentally, in order to form a bump electrode uniform in height on the wafer, agitation of the plating liquid to be supplied to the wafer surface has been carried out conventionally. As an agitation method, the following three methods are used.

As the first method, Japanese Laid-Open Patent Publication No. 31834/1996 (Tokukaihei 8-31834, published on Feb. 2, 1996) discloses a method of jetting a plating liquid by a multi-hole nozzle (plural nozzles) on a target plating surface of a wafer which is disposed so as to oppose a positive electrode.

FIG. 6 is an explanatory view of a plating apparatus for use in the foregoing method. As shown in FIG. 6, a plating apparatus 101 includes a plating liquid jet pump 102, plating liquid feed channels 103a, a positive electrode (anode electrode) 104, a negative electrode (cathode electrode) 105, and a tank section 107. Then, a wafer 111, in which plural semiconductor devices such as a transistor (not shown) are integrated, is supported with the cathode electrode 105 to be fixed to the plating apparatus 101. In this fixing, a surface for forming a bump electrode of the wafer 111 is fixed so as to face to the side of the tank section 107, which contains a plating liquid 106 (a wafer fixing step).

The plating liquid 106 is blown up through a plurality of plating liquid feed channels 103a provided in the plating apparatus 101 by the plating liquid jet pump 102. The plating liquid 106 reaches the surface for forming the bump electrode while being agitated inside the tank section 107 of the plating apparatus 101 (a plating liquid agitating step).

Then, voltage is applied between the foregoing anode electrode 104 and the cathode electrode 105 connected to a base metallic film 112 provided on the wafer 111, which passes the plating current through the base metallic film 112, so that a plating metal in the plating liquid 106 is deposited to form a bump electrode 13 (an electrode forming step).

The second method, as shown in FIG. 7, is a method using a plating apparatus 131 which is provided with a rotating agitator section 108 for making rotational motions inside the tank section 107. The plating liquid feed channel 103b in the plating apparatus 131 has a single-hole nozzle.

In the method using the plating apparatus 131, the wafer fixing step and the electrode forming step are the same as those of the first method. However, the plating liquid agitating step is different. More specifically, the plating liquid 106 is blown up through the plating liquid feed channel 103b provided in the plating apparatus 131. Also, the plating liquid 106 reaches the surface for forming the bump electrode of the wafer 111 while being agitated by the rotating agitator section 108 for making rotational motions.

The third method, as shown in FIG. 8, is a method using a plating apparatus 141 which is provided with a back-and-forth agitator section 109 for making back-and-forth motions inside the tank section 107. As the foregoing plating liquid feed channel 103b, the plating liquid feed channel 103b in the plating apparatus 141 has a single-hole nozzle.

In the method using the plating apparatus 141, the wafer fixing step and the electrode forming step are the same as those of the first and second methods. However, the plating liquid agitating step is different. More specifically, the plating liquid 106 is blown up through the plating liquid feed channel 103b provided in the plating apparatus 141. Also, the plating liquid 106 reaches the surface for forming the bump electrode of the wafer 111 while being agitated by the back-and-forth agitator section 109 for making back-and-forth motions in the directions indicated by an arrow P.

Note that, on the wafer 111 shown in FIGS. 6 through 8, an insulating film 114, an electrode pad 115, a protective film 116, the base metallic film 112, and a photo-resist film 117 are provided, which constructs a semiconductor integrated circuit 121. Further, an open arrow indicates a flow direction of the jetted plating liquid 106.

Further, in the above electrode forming step, the plating liquid 106 which has not reached the surface for forming the bump electrode and the plating liquid 106 which has not been used for the bump electrode 113 are arranged so as to be exhausted from the vicinity of the wafer 111 to the outside of the tank section 107.

However, in the first method, the plating liquid 106 blown up by the plating liquid jet pump 102 is branched through plural nozzles of the plating liquid feed channels 103a. This causes differences in flow of the plating liquid 106 between the nozzles, so that it might be difficult to form the bump electrode 113 completely uniform in height.

In the second method, the rotating agitator section 108 for agitating the plating liquid produces micro-bubbles (air bubbles) due to cavitation, in accordance with rotating conditions. When the air bubbles adhere on the wafer 111, the plating liquid 106 does not reach positions where the bump electrode 113 should be formed, so that it might be difficult to form the bump electrode 113 completely uniform in height. Besides, it might be difficult to form the bump electrode 113.

Also, in the third method, because the back-and-forth agitator section 109 is provided inside the tank section 107, the occurrence of the air bubbles arises the same problem as that of the second method.

Further, in the second and third methods, because agitator sections (the rotating agitator section 108 and the back-and-forth agitator section 109) are provided in the tank sections 107 of the respective plating apparatuses 131 and 141, structures (agitating structures) of the plating apparatuses 131 and 141 become complicated. This causes a burdensome maintenance for the plating apparatuses 131 and 141 and brings about increase in costs for the plating apparatuses 131 and 141 themselves.

### SUMMARY OF THE INVENTION

The first object of the present invention is to provide a manufacturing apparatus of a semiconductor integrated circuit having a bump electrode uniform in height. Further, the second object of the present invention is to provide a manufacturing method of the above semiconductor integrated circuit. Still further, the third object of the present invention is to provide the above semiconductor integrated circuit.

For achievement of the first object, in a manufacturing apparatus of a semiconductor integrated circuit of the present invention, which passes a current through a target plating surface of a semiconductor substrate, provided on a plating liquid, so as to provide a bump electrode on the semiconductor substrate by electrolytic plating method,

the manufacturing apparatus includes:

a positive electrode which is provided in a tank section for storing the plating liquid;

a negative electrode which is connected to the target plating surface of the semiconductor substrate; and

substrate vibrating means for causing the semiconductor substrate to vibrate up and down when the bump electrode is provided.

The manufacturing apparatus of the semiconductor integrated circuit of the present invention includes a positive electrode (anode electrode) and a negative electrode (cathode electrode).

The cathode electrode, which is arranged so as to connect to a target plating surface of a semiconductor substrate, is an electrode for absorbing positive ions (for emitting negative ions) in a plating liquid (electrolytic solution) by the electrolytic plating method. This causes a reaction of forming metallic ions making up the plating liquid into metal (for example, Au⁺+e⁻→Au; ion transport) on the above target plating surface, so that deposition of this metal forms the bump electrode.

The ion transport occurs in a minute region (micro-region), which is a thin part (several tens of A thick) above the target plating surface, where electrochemical double layers are positioned.

The manufacturing apparatus of the semiconductor integrated circuit of the present invention can form a bump electrode while vibrating the semiconductor substrate up and down. That is, a part for forming the bump electrode (a bump forming section) can be vibrated up and down. Therefore, it is possible to sufficiently agitate the plating liquid which reaches the bump forming section in the foregoing micro-region. This allows active ion transport at the bump forming section, so that it is possible to form a bump electrode having a uniform height. That is, it is possible to manufacture a semiconductor integrated circuit having a bump electrode uniform in height.

Different from the conventional manufacturing apparatus (conventional apparatus) of a semiconductor integrated circuit, the manufacturing apparatus of the semiconductor integrated circuit of the present invention can sufficiently agitate the plating liquid without providing plural nozzles or plating liquid agitator section. More specifically, the manufacturing apparatus of the semiconductor integrated circuit of the present invention causes no differences in flow of the plating liquid caused by the plural nozzles, and no micro-bubbles produced by the plating liquid agitator section, both of which are causes of a bump electrode with non-uniform height in the conventional apparatus.

Up-and-down vibrations of the semiconductor substrate allow agitation of the plating liquid in the direction of thickness of the electrochemical double layers. Therefore, it is possible to effectively prevent a rate-limiting of reaction by the ion transport, as compared with vibrations in the lateral direction (left-and-right direction).

In order to achieve the first object, in a manufacturing apparatus of a semiconductor integrated circuit of the present invention, which passes a current through a target plating surface of a semiconductor substrate, provided on a plating liquid, so as to provide a bump electrode on the semiconductor substrate by electrolytic plating method,

the manufacturing apparatus includes:

a positive electrode which is provided in a tank section for storing the plating liquid;

a negative electrode which is connected to the target plating surface of the semiconductor substrate;

an induction coil for causing the semiconductor substrate to vibrate through electromagnetic force; and

a high-frequency power source for supplying a high-frequency current to the induction coil.

According to the above arrangement, the manufacturing apparatus of the semiconductor integrated circuit of the present invention includes the induction coils and the high-frequency power source. The induction coils produce a magnetic field in response to a current supply from the high-frequency power source. Then, the magnetic field and the current which flows on the target plating surface produce electromagnetic force. The electromagnetic force can vibrate the semiconductor substrate including the target plating surface. As a result, it is possible to sufficiently agitate the plating liquid for reaching the bump forming section in the foregoing micro-region. This allows active ion transport at the bump forming section, so that it is possible to form a bump electrode having a uniform height. That is, it is possible to manufacture a semiconductor integrated circuit having a bump electrode uniform in height.

Further, in case where the semiconductor substrate is caused to vibrate using the electromagnetic force in such a manner, it is easy to optimize an amplitude and a cycle in the field of the electromagnetic force (electric field) and unnecessary to provide a moving part for vibrating the semiconductor substrate separately, so that it is possible to suppress the occurrence of malfunctions and troubles in the manufacturing apparatus itself.

Still further, it is possible to vibrate the semiconductor substrate up and down only by simple equipments, the induction coils and the high-frequency power source. Note that, the induction coils are provided in an area where the action of the magnetic field covers the semiconductor substrate.

Further, different from the conventional apparatus, the manufacturing apparatus of the semiconductor integrated circuit of the present invention can sufficiently agitate the plating liquid without providing plural nozzles or plating liquid agitator section. More specifically, the manufacturing apparatus of the semiconductor integrated circuit of the present invention causes no differences in flow of the plating liquid caused by the plural nozzles, and no micro-bubbles produced by the plating liquid agitator section, both of which are causes of a bump electrode with non-uniform height in the conventional apparatus.

In order to achieve the above second object, a manufacturing method of a semiconductor integrated circuit of the present invention, includes the steps of:

supplying a plating liquid to a target plating surface of a semiconductor substrate; and

providing a bump electrode on the target plating surface by electrolytic plating method while vibrating the semiconductor substrate up and down.

In the electrolytic plating method, caused is a reaction of forming metallic ions making up the plating liquid into metal (for example, Au⁺+e⁻→Au; ion transport) on the above target plating surface, so that deposition of this metal forms the bump electrode.

The ion transport occurs in a minute region (micro-region), which is a thin part (several tens of Å thick) above the target plating surface, where electrochemical double layers are positioned.

The manufacturing method of the semiconductor integrated circuit of the present invention can form a bump electrode while vibrating the semiconductor substrate up and down. That is, a part for forming the bump electrode (a bump forming section) can be vibrated up and down. Therefore, it is possible to sufficiently agitate the plating liquid for reaching the bump forming section in the foregoing micro-region. This allows active ion transport at the bump forming section, so that it is possible to form a bump electrode having a uniform height. That is, it is possible to manufacture a semiconductor integrated circuit having a bump electrode uniform in height.

Further, the manufacturing method of the semiconductor integrated circuit of the present invention can sufficiently agitate the plating liquid without using the conventional apparatus which is provided with plural nozzles or plating liquid agitator sections. More specifically, the manufacturing method of the semiconductor integrated circuit of the present invention causes no differences in flow of the plating liquid caused by the plural nozzles, and no micro-bubbles produced by the plating liquid agitator section, both of which are causes of a bump electrode with non-uniform height in the conventional manufacturing method of the semiconductor integrated circuit (conventional method).

Up-and-down vibrations of the semiconductor substrate allow agitation of the plating liquid in the direction of thickness of the electrochemical double layers. Therefore, it is possible to effectively prevent a rate-limiting of reaction by the ion transport, as compared with vibrations in the lateral direction (left-and-right direction).

In order to achieve the above second object, a manufacturing method of a semiconductor integrated circuit of the present invention, includes the steps of:

supplying a plating liquid to a target plating surface of a semiconductor substrate; and

providing a bump electrode on the target plating surface by electrolytic plating method while vibrating the semiconductor substrate through electromagnetic force.

According to the above arrangement, the manufacturing method of the semiconductor integrated circuit of the present invention can form the bump electrode while vibrating the semiconductor substrate up and down. That is, a part for forming the bump electrode (a bump forming section) can be vibrated up and down. Therefore, it is possible to sufficiently agitate the plating liquid for reaching the bump forming section in the foregoing micro-region. This allows active ion transport at the bump forming section, so that it is possible to form a bump electrode having a uniform height. That is, it is possible to manufacture a semiconductor integrated circuit having a bump electrode uniform in height.

Further, the manufacturing method of the semiconductor integrated circuit of the present invention can sufficiently agitate the plating liquid without using the conventional apparatus which is provided with plural nozzles or plating liquid agitator sections. More specifically, the manufacturing method of the semiconductor integrated circuit of the present invention causes no differences in flow of the plating liquid caused by the plural nozzles, and no micro-bubbles produced by the plating liquid agitator section, both of which are causes of a bump electrode with non-uniform height in the conventional method.

Further, in case where the semiconductor substrate is caused to vibrate using the electromagnetic force in such a manner, it is easy to optimize an amplitude and a cycle in the field of the electromagnetic force (electric field) and unnecessary to provide a moving part for vibrating the semiconductor substrate separately, so that it is possible to suppress the occurrence of malfunctions and troubles of the manufacturing apparatus itself.

For achievement of the third object, it is preferable that the semiconductor integrated circuit of the present invention is manufactured by the above manufacturing method of the semiconductor integrated circuit.

According to the above arrangement, the semiconductor integrated circuit is manufactured while the semiconductor substrate is vibrated up and down, for example, through electromagnetic force. This provides a semiconductor integrated circuit having a bump electrode uniform in height.

For a fuller understanding of the nature and advantages of the invention, reference should be made to the ensuing detailed description taken in conjunction with the accompanying drawings.

### BRIEF DESCRIPTION OF THE DRAWINGS

FIG. 1 is an explanatory view of a manufacturing apparatus of a semiconductor integrated circuit according to one embodiment of the present invention.

FIG. 2 is an explanatory view of a semiconductor integrated circuit manufactured by the manufacturing apparatus of the semiconductor integrated circuit shown in FIG. 1.

FIG. 3(a) is an explanatory view of one example of vibration of a wafer, seen from a side of the wafer and an induction coil of the semiconductor integrated circuit shown in FIG. 1, and FIG. 3(b) is an explanatory view of vibration of the wafer, seen from upside of the wafer and the induction coil shown in FIG. 3(a).

FIG. 4(a) is an explanatory view of another example of FIG. 3(a), and FIG. 4(b) is an explanatory view of vibration of the wafer, seen from upside of the wafer and the induction coil shown in FIG. 4(a).

FIG. 5 is a graph showing variation in height of the respective bump electrodes formed by the manufacturing apparatus of the semiconductor integrated circuit of the present invention and the conventional manufacturing apparatus (conventional apparatus) of the semiconductor integrated circuit of FIGS. 6 through 8 shown later.

FIG. 6 is an explanatory view of the conventional manufacturing apparatus of the semiconductor integrated circuit.

FIG. 7 is an explanatory view of another conventional manufacturing apparatus of the semiconductor integrated circuit, different from the manufacturing apparatus of FIG. 6.

FIG. 8 is an explanatory view of still another conventional manufacturing apparatus of the semiconductor integrated circuit, different from the manufacturing apparatuses of FIGS. 6 and 7.

### DESCRIPTION OF THE EMBODIMENTS

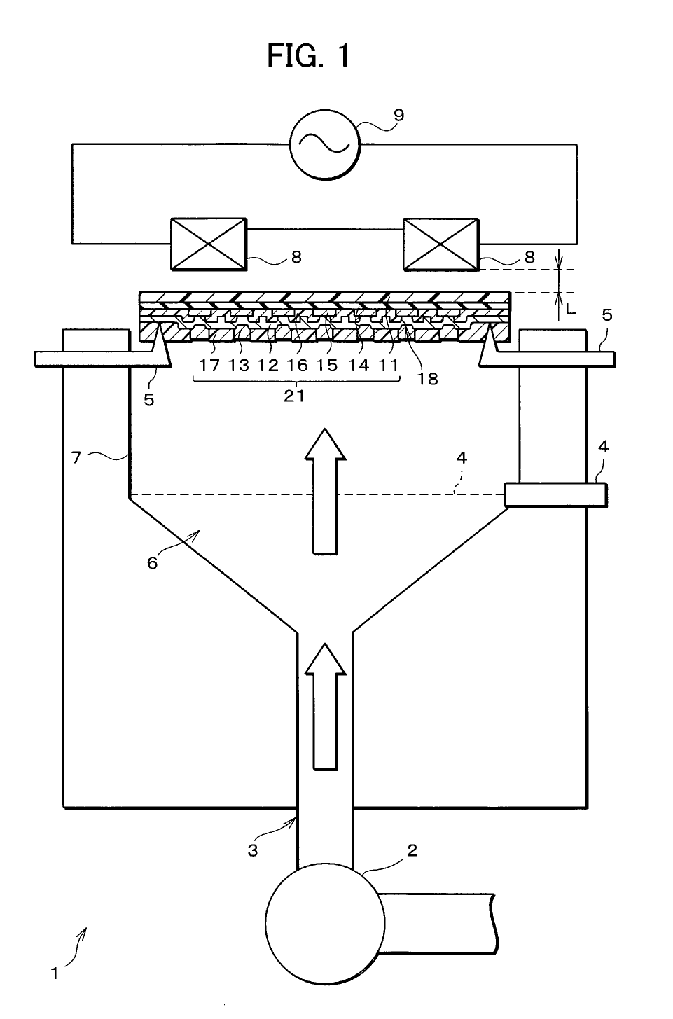

Referring to FIGS. 1 through 5, the following will describe one embodiment of the present invention.

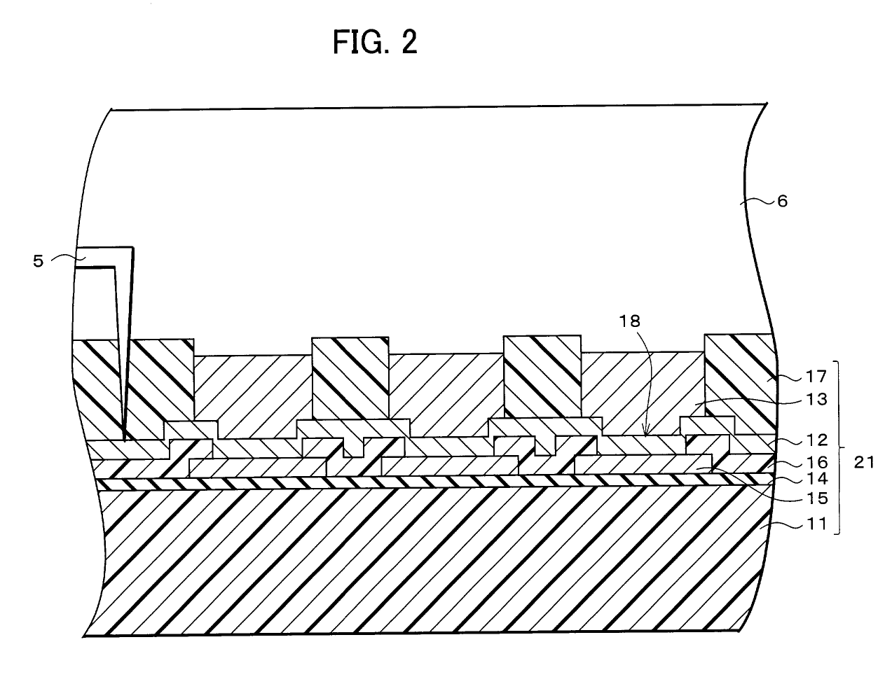

FIG. 1 is an explanatory view of a manufacturing apparatus 1 (the present plating apparatus) of a semiconductor integrated circuit according to the present embodiment. FIG. 2 is an explanatory view of a semiconductor integrated circuit 21 manufactured by the present plating apparatus 1. Note that, the semiconductor integrated circuit 21 manufactured by the present plating apparatus 1 is also shown in FIG. 1. Further, for convenience of the explanation, the semiconductor integrated circuit 21 of FIG. 1 is shown upside down in FIG. 2.

As shown in FIG. 1, the present plating apparatus 1 includes a plating liquid jet pump 2, a plating liquid feed channel 3, a positive electrode (anode electrode) 4, a negative electrode (cathode electrode) 5, a tank section 7, induction coils 8 (substrate vibrating means), and a high-frequency power source 9 (substrate vibrating means).

The plating liquid jet pump 2 is one for supplying a plating liquid 6 to the plating liquid feed channel 3. Note that, the plating liquid 6 is an electrolytic solution including gold (Au).

The plating liquid feed channel 3, which is a so-called nozzle, is one for jetting the supplied plating liquid 6 toward the surface (target plating surface) of a wafer 11 (described later).

The anode electrode 4 is an electrode for absorbing negative ions (for emitting positive ions) in the plating liquid 6, and the cathode electrode 5 is an electrode for absorbing positive ions (for emitting negative ions) in the plating liquid 6.

The tank section 7 is one for storing the plating liquid 6.

The induction coil 8, a coiled lead wire, produces a magnetic field when a current is passed through the lead wire. The magnetic field and a current flowing through a base metallic film 12 (described later) of the wafer 11 causes electromagnetic induction, which produces electromagnetic force. That is, the induction coil 8 produces the electromagnetic force to vibrate the wafer 11. Note that, the induction coil 8 may be provided at any positions, provided that the action of the electromagnetic induction covers the wafer 11.

The high-frequency power source 9 is one for passing a high-frequency current through the induction coil 8. Note that, a frequency (current frequency) and an amplitude of the high-frequency current is determined in the consideration of viscosity of the plating liquid 6, type and density of the metallic ions in the plating liquid 6, size and quantity of the wafer 11, impedance as a system including the base metallic film 12 of the wafer 11, the anode electrode 4, and the plating liquid 6, and the others (hereinafter these are referred to as “electrolytic plating conditions”).

Further, as shown in FIG. 2, the semiconductor integrated circuit 21 includes the wafer 11, an insulating film 14, an electrode pad 15, a protective film 16, the base metallic film 12, a photo-resist film 17, and a bump electrode 13.

The wafer 11, made of, for example, silicon, is a substrate of the semiconductor integrated circuit 21 which integrates semiconductor devices not shown.

The insulating film 14 is, for example, a silicon dioxide (SiO₂) film, which is caused by oxidization of the surface of the wafer 11 (oxidization of silicon). The insulating film 14, provided on the wafer 11, is a film for insulating from outside.

The electrode pad 15 is an electrical terminal including input and output terminals of the semiconductor device which is integrated in the wafer 11. Also, the electrode pad 15 is made by the following step: aluminum (Al) is deposited approximately 1 μm thick on the insulating film 14 by sputtering, thereafter it is formed into a desired shape by photolithography and etching.

The protective film 16, positioned on the insulating film 14 and the electrode pad 15, is a film for protecting these surfaces. The protective film 16 is made of silicon dioxide (SiO₂) or silicon nitride (Si₃N₄) deposited in the order of 1 μm thick by chemical reaction of the wafer 11 (the wafer 11 made of silicon) by CVD method (Chemical Vapor Deposition method). Note that, for connection between the base metallic film 12 described later and the electrode pad 15, the protective film 16 has openings (has pad opening sections) provided above the parts where the electrode pad 15 are provided.

The base metallic film 12 is a current film (a film passing current) for applying a current by an electrolytic plating method. The base metallic film 12 is made up of single metal or plural types of metals (composition metal) deposited on the protective film 16 and in the pad opening sections by sputtering.

The photo-resist film 17 serves as a mask for forming the bump electrode 13 at a desired part (a part for forming the bump electrode 13; a bump forming section 18) on the base metallic film 12. The photo-resist film 17 is made by applying material photosensitive for ultraviolet rays on the base metallic film 12, exposing the parts corresponding to the bump forming section 18, and then, processing by development and etching. That is, the photo-resist film 17 is a film including opening sections (photo-resist opening section) for exposure of the bump forming section 18.

The bump electrode 13 is an electrode for electrical and physical connection between the electrode pad 15 and wires (not shown) provided on a mounting substrate for mounting the semiconductor integrated circuit 21. The bump electrode 13 is made of gold (Au) by the electrolytic plating method.

The electrolytic plating method is a method in which the passage of current through positive and negative electrodes in an electrolytic solution causes ion transport of electrochemical double layers as a region for electrochemical reaction (transition region), whereby metallic ions are deposited to the negative electrode.

More specifically, the passage of current through the anode electrode 4 and the cathode electrode 5 in the plating liquid 6 causes the reaction: Au⁺+e⁻→Au, whereby gold (Au) is deposited on the base metallic film 12 (on the bump forming section 18) connected to the cathode electrode 5 to form the bump electrode 13.

The ion transport of the electrochemical double layers has an influence on a forming rate (plating forming rate) of the bump electrode 13, which has an influence on uniformity in height of the bump electrode 13, accordingly. Therefore, it is preferable to activate the ion transport. The electrochemical double layers are provided in a very thin part (several tens of Å thick) above the surface of the base metallic film 12.

Note that, the thin part is a micro region hereinafter.

Next, the following will describe a forming step of the bump electrode 13 in the semiconductor integrated circuit 21 by using the present plating apparatus 1.

First, on the wafer 11 provided are the insulating film 14, the electrode pad 15, the protective film 16, the base metallic film 12, and the photo-resist film 17. Especially, the photo-resist film 17 is provided with photo-resist opening sections.

The base metallic film 12 (the bump forming section 18) exposed from the photo-resist opening sections is fixed so as to be supported by the cathode electrode 5, facing to the tank section 7 of the present plating apparatus 1. At this point, the base metallic film 12 is fixed so as to make contact (connect) with the cathode electrode 5.

Secondly, the high-frequency power source 9 supplies a high-frequency current to the induction coils 8. Then, the induction coils 8 cause the magnetic field due to the current, and the action of electromagnetic induction by the magnetic field produces high-frequency vibration of the wafer 11.

The plating liquid jet pump 2 blows up the plating liquid 6 through the plating liquid feed channel 3. Then, the plating liquid 6 blown up reaches the bump forming section 18, which is provided on the wafer 11. Note that, when the plating liquid 6 reaches the bump forming section 18, the wafer 11 agitates the plating liquid 6 by the high-frequency vibration.

Finally, voltage is applied between the anode electrode 4 and the cathode electrode 5. The base metallic film 12 and the cathode electrode 5 are electrically connected, so that the voltage is applied between the base metallic film 12 and the anode electrode 4. Accordingly, the base metallic film 12 passes a current (plating current), which changes the plating liquid 6 which has reached the bump forming section 18 of the base metallic film 12 into gold (Au). That is, the gold (Au) is deposited to form the bump electrode 13.

By the above forming step the bump electrode 13 is formed. Note that, the plating liquid 6 which has not reached the surface for forming a bump electrode and the plating liquid 6 which has not been used for the bump electrode 13 are arranged so as to be exhausted from the vicinity of the wafer 11 to the outside of the tank section 7.

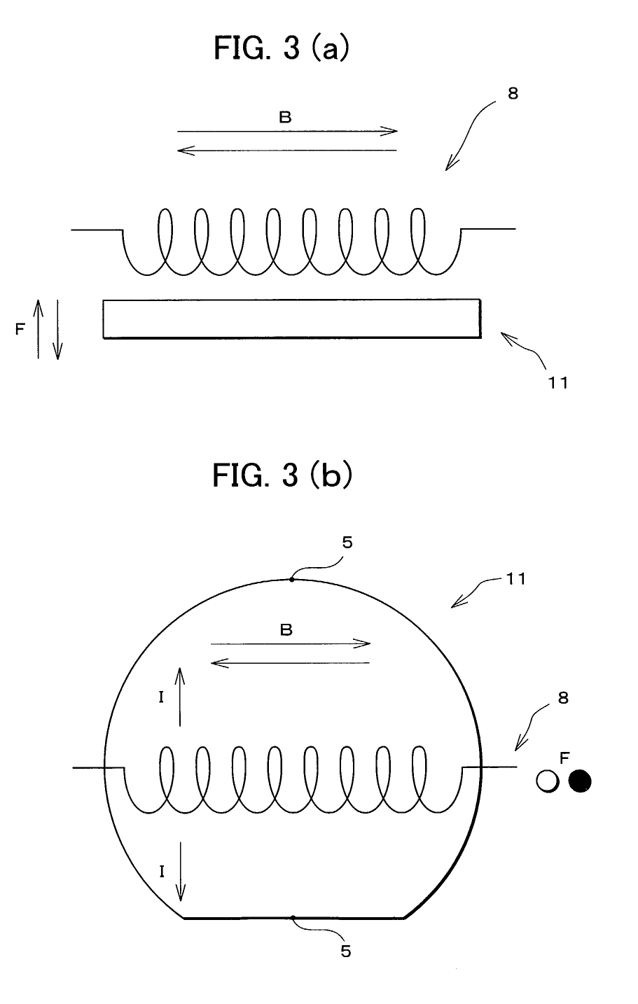

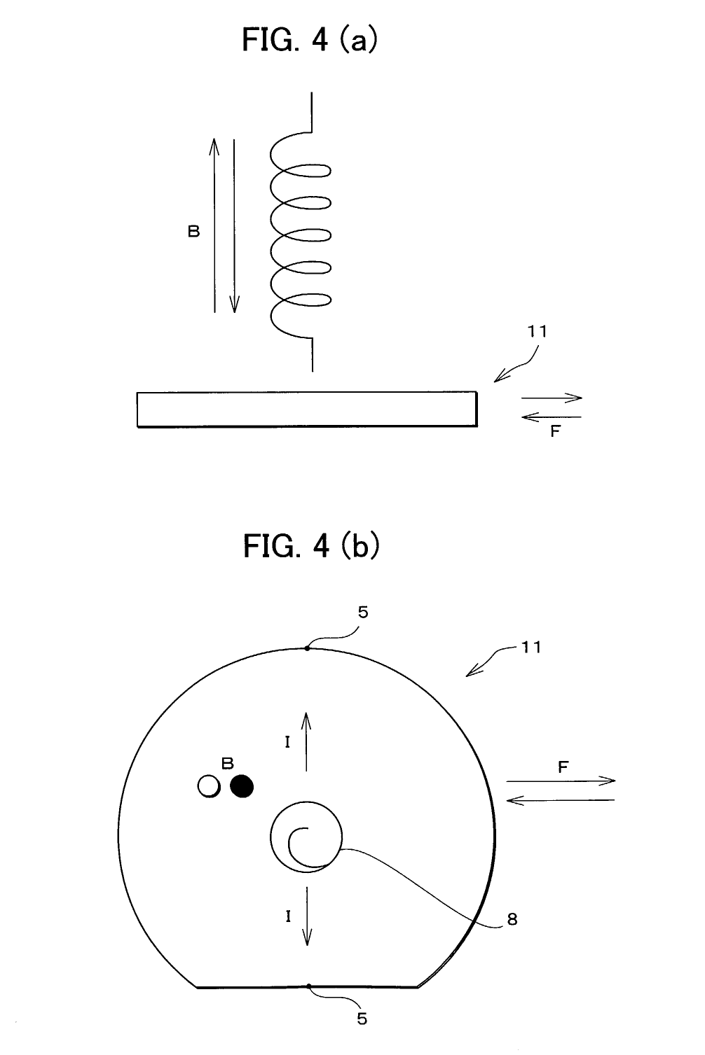

Here, referring to FIGS. 3(a), 3(b), 4(a), and 4(b), the following will describe the direction of the wafer 11's vibration caused by the induction coils 8, a characteristic component in the present plating apparatus 1. FIG. 3(a) and FIG. 4(a) are explanatory views, seen from the side of the wafer 11 and the induction coil 8 shown in FIG. 1. FIG. 3(b) and FIG. 4(b) are explanatory views, seen from upside of the wafer 11 and the induction coil 8. When directions are shown in the drawings, ∘ (open circle) denotes a direction from the bottom to the top of the drawings. ● (black circle) denotes a direction from the top to the bottom of the drawings. Further, arrows B, I, and F denote a magnetic field direction, a current direction, and an electromagnetic force direction, respectively.

FIG. 3(a) shows the case where the current-carrying induction coil 8, disposed in the parallel direction to the wafer 11, produces the magnetic field in the direction of the arrow B. According to such a case, as shown in FIG. 3(b), electromagnetic induction by the current in the direction of the arrow I flowing through the base metallic film (not shown in FIG. 3(b)) and the magnetic field in the direction of the arrow B produces electromagnetic force in the direction of the arrow F, and the wafer 11 vibrates in the direction of the arrow F (up-and-down vibration).

FIG. 4(a) shows the case where the current-carrying induction coil 8, disposed in the vertical direction to the wafer 11, produces the magnetic field in the direction of the arrow B. According to such a case, as shown in FIG. 4(b), electromagnetic induction by the current in the direction of the arrow I flowing through the base metallic film (not shown in FIG. 4(b)) and the magnetic field in the direction of the arrow B produces electromagnetic force in the direction of the arrow F, and the wafer 11 vibrates in the direction of the arrow F (left-to-right vibration).

In the present plating apparatus 1, as the above vibrating directions, the wafer 11 may make the up-and-down vibration, or the left-to-right vibration. Moreover, the frequency of the vibrations (vibration frequency) is not limited especially; however, the frequency is preferable from several tens of Hz to several MHz. More preferably, the frequency is 10 KHz to 20 KHz (an audio frequency). The vibration frequency can be changed in accordance with the amplitude and current frequency of the high-frequency current which is supplied from the high-frequency power source 9 to the induction coil 8.

Further, the vibrating directions can be found by so-called “Fleming's left-hand rule.”

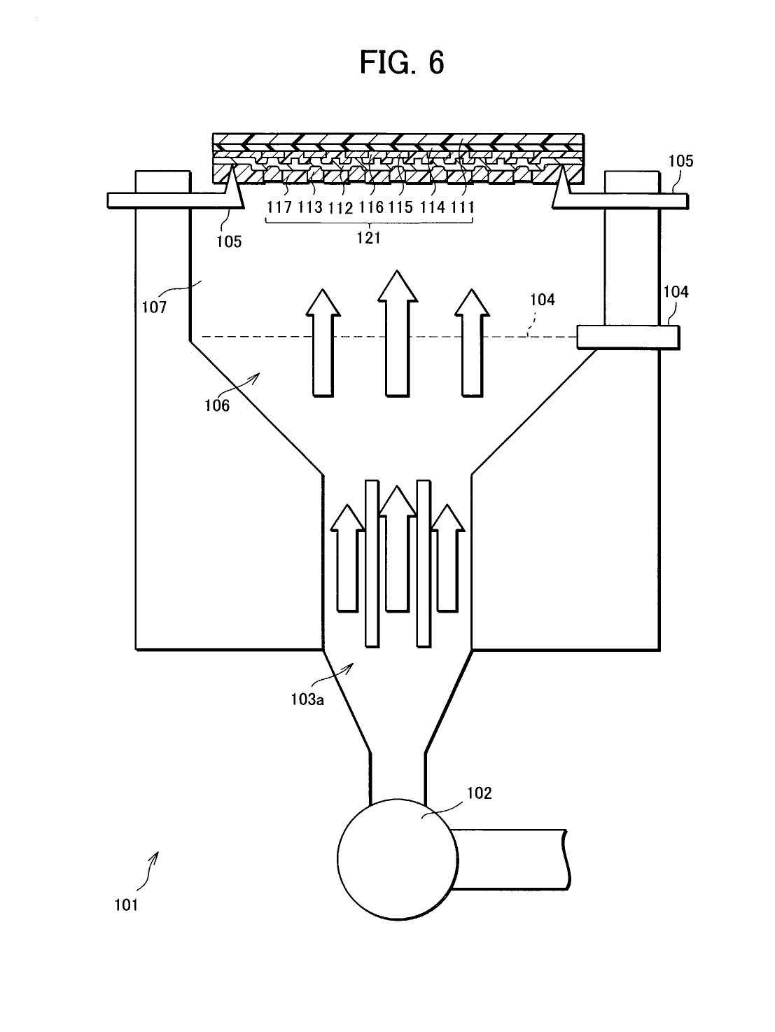

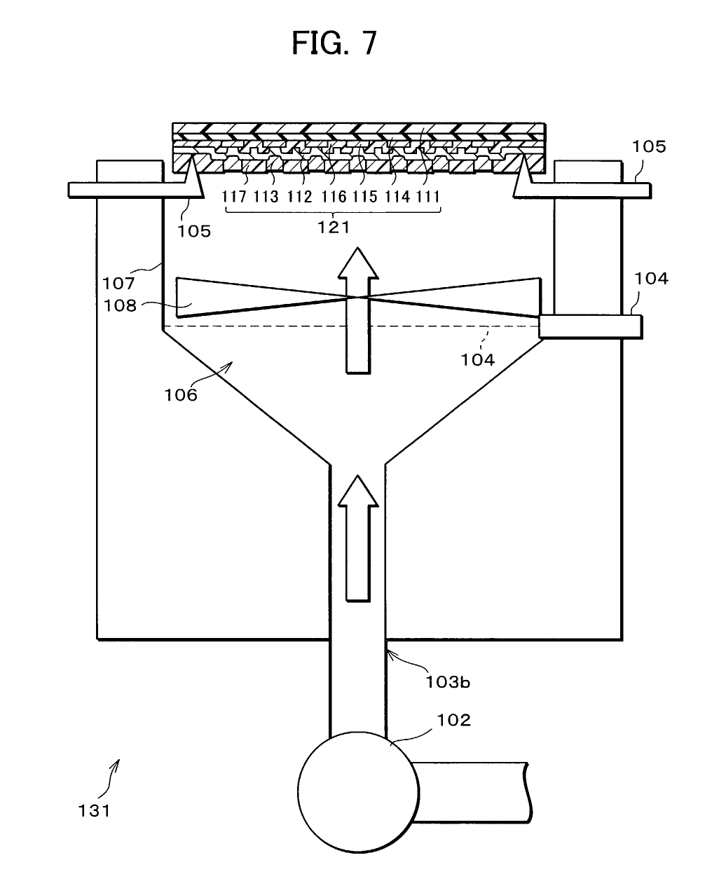

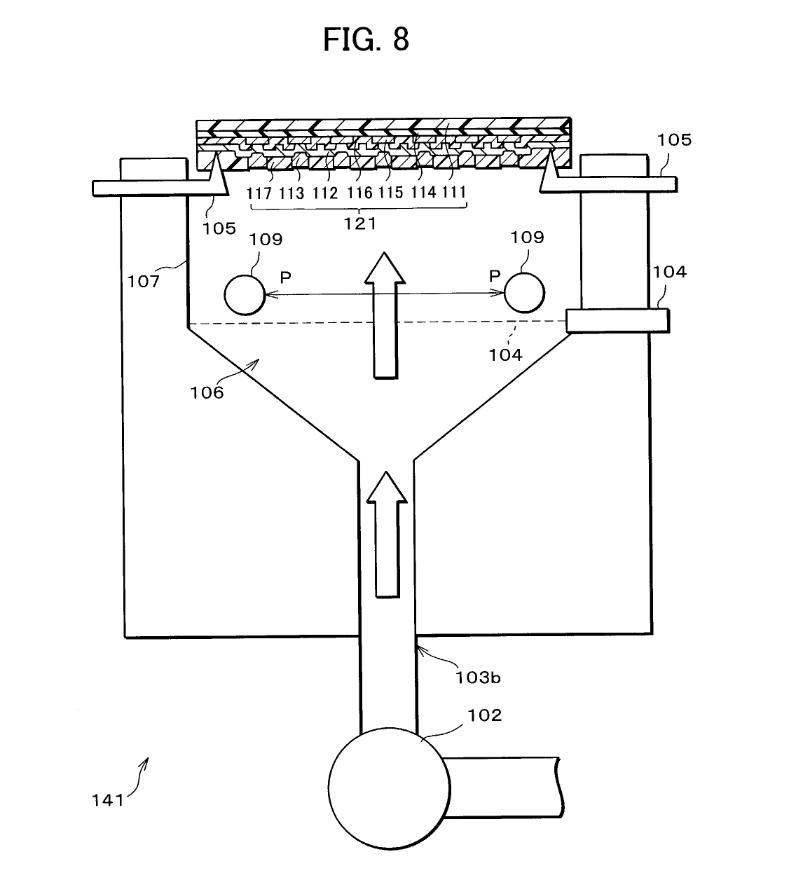

As described above, the present plating apparatus 1 can form the bump electrode 13 while vibrating the wafer 11. Incidentally, in the conventional apparatuses 101, 131, and 141 (see FIGS. 6 through 8), the plating liquid 106 is agitated roughly, so that, in some cases, the plating liquid 106 is not sufficiently agitated at a part for forming the bump electrode 113 on the base metallic film 112 (bump forming section), that is, in a minute region (micro-region) where electrochemical double layers are positioned. This has caused inactivation of the ion transport and non-uniformity in height of the bump electrode 113, and difficulty in formation of the bump electrode 113.

However, the present plating apparatus 1 can sufficiently vibrate the bump forming section 18 through vibration of the wafer 11 itself by being provided with simple devices, the induction coil 8 and the high-frequency power source 9. Therefore, it is possible to sufficiently agitate the plating liquid 6 which reaches the bump forming section 18 (possible to make an ideal state of agitating). This allows active ion transport at the bump forming section 18, so that it is possible to form the bump electrode 13 having a uniform height.

Especially, the present plating apparatus 1 allows up-and-down vibration of the wafer 11, so that it is possible to agitate the plating liquid 6 in the direction of thickness of the electrochemical double layers. Therefore, it is possible to effectively prevent a rate-limiting of reaction by the ion transport, as compared with vibrations in the lateral direction (left-and-right direction).

Further, the present plating apparatus 1 can vibrate the wafer 11 through electromagnetic force, as described above. In case where the wafer 11 is caused to vibrate using the electromagnetic force in such a manner, it is easy to optimize an amplitude and a cycle in the field of the electromagnetic force (electric field) and unnecessary to provide a moving part for vibrating the wafer 11 separately, so that it is possible to suppress the occurrence of malfunctions and troubles in the present plating apparatus itself.

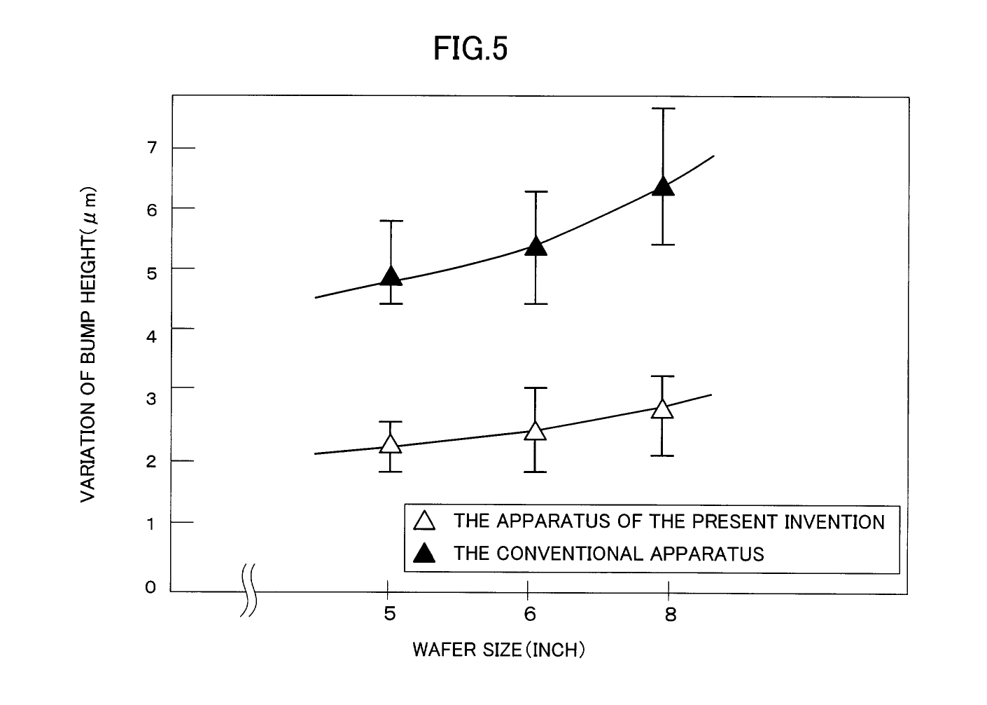

Note that, FIG. 5 is a graph showing average values and ranges as to variation in height of the bump electrode in case where the bump electrode is provided on the wafer by using the plating apparatus of the present invention (apparatus of the present invention) and the conventional plating apparatus (conventional apparatus). As shown in the graph, in any cases of 5-inch-diameter wafer, 6-inch-diameter wafer, and 8-inch-diameter wafer, it is clear that the bump electrode formed by the apparatus of the present invention has a little variation in height and obtains an excellent result.

Further, the induction coils 8 in the present plating apparatus 1 may be provided at any positions, provided that the action of the electromagnetic induction covers the wafer 11. However, it is preferable that the induction coils 8 are provided on the opposite surface of the target plating surface so as not to make contact with the plating liquid 6.

In such a manner, different from the conventional apparatuses 131 and 141, the present plating apparatus 1 needs no agitator section (the rotating agitator section 108 or the back-and-forth agitator section 109) inside the tank section 107. More specifically, the induction coils 8 corresponding to the agitator section 108 or 109 are provided outside the tank section 7, so that it is possible to prevent the occurrence of micro-bubbles, which occurs in the plating liquid because of the agitator section 108 or 109. In addition, a simple structure of plating liquid agitator in the present plating apparatus 1 makes it possible to suppress the increase in manufacturing cost of the present plating apparatus 1 itself.

Further, no contact with the plating liquid 6 keeps the induction coils 8 clean. Accordingly, maintenance of the induction coils 8 can be reduced.

Still further, the present plating apparatus 1 causes no differences in flow of the plating liquid caused by the plural nozzles, which has been a problem in the conventional apparatus 101.

Yet further, it is preferable that the induction coils 8, as shown in FIG. 1, are provided at a distance L away from the opposite surface (the surface having no plating) of the target plating surface of the wafer 11.

The distance L is such a distance that the wafer 11, which vibrates up and down through electromagnetic force, and the induction coils 8 make no contact with each other. In such a manner, it is possible to make the wafer 11 to vibrate up and down while preventing the above contact.

Further, the induction coil 8 may have any shape, provided that the size of the shape is not more than a diameter of the wafer 11. Still further, the number of the induction coil 8 is not particularly limited; however, it is preferable that the induction coil 8 is provided in plurality.

Plural induction coils 8, each of which has a size of not more than the diameter of the wafer 11, can obtain larger electromagnetic force, as compared with a single induction coil 8. Further, the size of the induction coil 8 is not more than the diameter of the wafer 11, so that the present plating apparatus 1 can be downsized.

Further, the high-frequency power source 9 can vary an amplitude and a frequency (current frequency) of an alternating current. Accordingly, it is possible to vary vibration frequency for vibrating the wafer 11. Therefore, under various electrolytic plating conditions, it is possible to more sufficiently vibrate a micro region where the electrochemical double layers are positioned.

Note that, in the apparatus of the present invention (the present plating apparatus; see FIG. 1), which obtains the result shown in FIG. 5, the induction coils 8 is made from approximately 100 turns of 2-mm-diameter coated copper wire, wound on a cylindrical insulating material in approximately 5-cm-diameter and 2-cm-height. Two induction coils 8 are provided at approximately 1 cm away from the back surface of the wafer 11 (the surface not facing to the tank section 7 of the present plating apparatus 1) so as to be symmetrical. The high-frequency power source 9 applies to the induction coils 8 an alternating current arranged by voltage (amplitude) adjustment so as to have an approximately 10 KHz frequency and an approximately 100 mA current.

Further, in the present embodiment, explained is a case where the action of the electromagnetic induction by the induction coil 8 is adopted to vibrate the wafer 11; however, the present invention is not limited to this, and other actions for vibrating the wafer 11 may be adopted.

Note that, the present plating apparatus 1 can vibrate the wafer 11 in a subtle manner, so that it is possible to make the plating liquid 6 in an ideal state of agitating and to improve uniformity in height of the bump electrode 13 in forming the bump electrode 13 by electrolytic plating method.

Also, it can be said that the present invention can provide a manufacturing method of a semiconductor integrated circuit in which the present plating apparatus 1 can form the bump electrode 13 having a uniform height by directly agitating the electrochemical double layers as a region for reaction of the base metallic film 12, without complex structure inside the tank section 7.

Further, the conventional apparatuses 131 and 141, which are provided with respective agitator sections (the rotating agitator section 108 and the back-and-forth agitator section 109) inside the tank section 107, have complex structures, causing large costs for remodeling. Therefore, formation of the bump electrode 113 by using the conventional apparatuses 131 and 141 causes increase in costs of the semiconductor integrated circuit. Still further, the complex structures also cause a large amount of labor for maintenance of the conventional apparatuses 131 and 141.

On the other hand, the present plating apparatus 1 is provided with the induction coils 8 as the agitator section outside the tank section 7, which allows small costs for remodeling and easy maintenance. Also, formation of the bump electrode 13 by using the present plating apparatus 1 minimizes the increase in costs of the semiconductor integrated circuit 21.

Further, the present invention can be expressed as a semiconductor integrated circuit, a manufacturing method of the semiconductor integrated circuit, and a manufacturing apparatus of the semiconductor integrated circuit as described below.

In a manufacturing apparatus of a semiconductor integrated circuit of the present invention, electrolytic plating is carried out by applying voltage between a metallic thin film, deposited over the front surface of the semiconductor substrate integrating plural semiconductor devices, and the positive electrode opposing the semiconductor substrate through the plating liquid, wherein the induction coil may be provided for vibrating the semiconductor substrate itself.

The substrate vibrating means may be provided with the induction coils for vibrating the semiconductor substrate through electromagnetic force and the high-frequency power source for supplying a high-frequency current to the induction coils.

In a manufacturing apparatus of a semiconductor integrated circuit of the present invention, which passes a current through a target plating surface of a semiconductor substrate, provided on a plating liquid, so as to provide a bump electrode on the semiconductor substrate by electrolytic plating method,

the manufacturing apparatus may include:

a positive electrode which is provided in a tank section for storing the plating liquid;

a negative electrode which is connected to the target plating surface of the semiconductor substrate; and

substrate vibrating means for causing the semiconductor substrate to vibrate up and down when the bump electrode is provided.

Further, the substrate vibrating means may include:

an induction coil for causing the semiconductor substrate to vibrate through electromagnetic force; and

a high-frequency power source for supplying a high-frequency current to the induction coil.

In a manufacturing apparatus of a semiconductor integrated circuit of the present invention, which passes a current through a target plating surface of a semiconductor substrate, provided on a plating liquid, so as to provide a bump electrode on the semiconductor substrate by electrolytic plating method,

the manufacturing apparatus may include:

a positive electrode which is provided in a tank section for storing the plating liquid;

a negative electrode which is connected to the target plating surface of the semiconductor substrate;

an induction coil for causing the semiconductor substrate to vibrate through electromagnetic force; and

a high-frequency power source for supplying a high-frequency current to the induction coil.

In the manufacturing apparatus of the semiconductor integrated circuit of the present invention, the induction coil may be provided in the area where the action of the magnetic field produced by the induction coil covers the semiconductor substrate.

Further, in the manufacturing apparatus of the semiconductor integrated circuit of the present invention, the induction coil may be provided outside the plating liquid.

Still further, in the manufacturing apparatus of the semiconductor integrated circuit of the present invention, the induction coil may be provided at a predetermined distance away from the back surface of the semiconductor substrate.

Yet further, the manufacturing apparatus of the semiconductor integrated circuit of the present invention may be able to optimize the amplitude of the vibration in the semiconductor substrate for that of electrochemical double layers in electrolytic plating method by varying an amplitude and a frequency of an alternating current to be supplied to the induction coil.

Further, in the manufacturing apparatus of the semiconductor integrated circuit of the present invention, the induction coil, being not more than the diameter of the semiconductor substrate, may be provided in plurality.

Still further, a manufacturing method of the semiconductor integrated circuit of the present invention may use a manufacturing apparatus of a semiconductor integrated circuit, which includes: means for applying voltage between a metallic thin film, deposited over the front surface of the semiconductor substrate incorporating plural semiconductor integrated circuit devices, and the positive electrode opposing the semiconductor substrate through the plating liquid; and means for passing an alternating current through the induction coils provided for vibrating the semiconductor substrate.

Further, the semiconductor integrated circuit of the present invention may be manufactured by the above manufacturing method of the semiconductor integrated circuit. Still further, the semiconductor integrated circuit of the present invention may be manufactured by the above manufacturing apparatus of the semiconductor integrated circuit.

As described above, in a manufacturing apparatus of a semiconductor integrated circuit of the present invention, which passes a current through a target plating surface of a semiconductor substrate, provided on a plating liquid, so as to provide a bump electrode on the semiconductor substrate by electrolytic plating method,

the manufacturing apparatus includes:

a positive electrode which is provided in a tank section for storing the plating liquid;

a negative electrode which is connected to the target plating surface of the semiconductor substrate; and

substrate vibrating means for causing the semiconductor substrate to vibrate up and down when the bump electrode is provided.

The manufacturing apparatus of the semiconductor integrated circuit according to the present invention includes a positive electrode (anode electrode) and a negative electrode (cathode electrode).

The cathode electrode, which is arranged so as to connect to a target plating surface of a semiconductor substrate, is an electrode for absorbing positive ions (for emitting negative ions) in a plating liquid (electrolytic solution) by the electrolytic plating method. This causes a reaction of forming metallic ions making up the plating liquid into metal (for example, Au⁺+e⁻→Au; ion transport) on the above target plating surface, so that deposition of this metal forms the bump electrode.

The ion transport occurs in a minute region (micro-region), which is a thin part (several tens of Å thick) above the target plating surface, where electrochemical double layers are positioned.

The manufacturing apparatus of the semiconductor integrated circuit of the present invention can form a bump electrode while vibrating the semiconductor substrate up and down. That is, a part for forming the bump electrode (a bump forming section) can be vibrated up and down. Therefore, it is possible to sufficiently agitate the plating liquid which reaches the bump forming section in the foregoing micro-region. This allows active ion transport at the bump forming section, so that it is possible to form a bump electrode having a uniform height. That is, it is possible to manufacture a semiconductor integrated circuit having a bump electrode uniform in height.

Different from the conventional manufacturing apparatus (conventional apparatus) of a semiconductor integrated circuit, the manufacturing apparatus of the semiconductor integrated circuit of the present invention can sufficiently agitate the plating liquid without providing plural nozzles or plating liquid agitator section. More specifically, the manufacturing apparatus of the semiconductor integrated circuit of the present invention causes no differences in flow of the plating liquid caused by the plural nozzles, and no micro-bubbles produced by the plating liquid agitator section, both of which are causes of a bump electrode with non-uniform height in the conventional apparatus.

Up-and-down vibrations of the semiconductor substrate allow agitation of the plating liquid in the direction of thickness of the electrochemical double layers. Therefore, it is possible to effectively prevent a rate-limiting of reaction by the ion transport, as compared with vibrations in the lateral direction (left-and-right direction).

In order to achieve the above object, in a manufacturing apparatus of a semiconductor integrated circuit of the present invention, which passes a current through a target plating surface of a semiconductor substrate, provided on a plating liquid, so as to provide a bump electrode on the semiconductor substrate by electrolytic plating method,

the manufacturing apparatus includes:

a positive electrode which is provided in a tank section for storing the plating liquid;

a negative electrode which is connected to the target plating surface of the semiconductor substrate;

an induction coil for causing the semiconductor substrate to vibrate through electromagnetic force; and

a high-frequency power source for supplying a high-frequency current to the induction coil.

According to the above arrangement, the manufacturing apparatus of the semiconductor integrated circuit of the present invention includes the induction coils and the high-frequency power source. The induction coils produce a magnetic field in response to a current supply from the high-frequency power source. Then, the magnetic field and the current which flows on the target plating surface produce electromagnetic force. The electromagnetic force can vibrate the semiconductor substrate including the target plating surface. As a result, it is possible to sufficiently agitate the plating liquid for reaching the bump forming section in the foregoing micro-region. This allows active ion transport at the bump forming section, so that it is possible to form a bump electrode having a uniform height. That is, it is possible to manufacture a semiconductor integrated circuit having a bump electrode uniform in height.

Further, in case where the semiconductor substrate is caused to vibrate using the electromagnetic force in such a manner, it is easy to optimize an amplitude and a cycle in the field of the electromagnetic force (electric field) and unnecessary to provide a moving part for vibrating the semiconductor substrate separately, so that it is possible to suppress the occurrence of malfunctions and troubles in the manufacturing apparatus itself.

Still further, it is possible to vibrate the semiconductor substrate up and down only by simple equipments, the induction coils and the high-frequency power source. Note that, the induction coils are provided in an area where the action of the magnetic field covers the semiconductor substrate.

Further, different from the conventional apparatus, the manufacturing apparatus of the semiconductor integrated circuit of the present invention can sufficiently agitate the plating liquid without providing plural nozzles or plating liquid agitator section. More specifically, the manufacturing apparatus of the semiconductor integrated circuit of the present invention causes no differences in flow of the plating liquid caused by the plural nozzles, and no micro-bubbles produced by the plating liquid agitator section, both of which are causes of a bump electrode with non-uniform height in the conventional apparatus.

Further, in addition to the above arrangement, in the manufacturing apparatus of the semiconductor integrated circuit of the present invention, it is preferable that the induction coil is provided outside the tank section.

According to the above arrangement, the induction coil, a member for agitating the plating liquid, is not provided inside the tank section, so that structure for agitating the plating liquid becomes simple. Therefore, it is possible to suppress increase in manufacturing costs for the manufacturing apparatus itself of the semiconductor integrated circuit of the present invention.

In addition, the induction coils are not positioned inside the tank section. Therefore, no contact with the plating liquid keeps the induction coils clean. Accordingly, maintenance of the induction coils can be reduced.

Further, in the manufacturing apparatus of the semiconductor integrated circuit of the present invention, it is preferable that the induction coil is provided at a predetermined distance away from other surface of the semiconductor substrate, which is on an opposite side of the tank section.

According to the above arrangement, the semiconductor substrate, which vibrates through electromagnetic force, can be caused to vibrate up and down without contacting with the induction coils.

Further, in the manufacturing apparatus of the semiconductor integrated circuit of the present invention, in addition to the above arrangement, it is preferable that the induction coil is smaller in size than the semiconductor integrated circuit and is provided in plurality.

According to the above arrangement, it is arranged so that, for example, plural induction coils, each having a size of not more than a diameter of a circular semiconductor substrate, are provided. Therefore, plural induction coils can obtain larger electromagnetic force, as compared with a single induction coil, so that it is possible to effectively vibrate the semiconductor substrate. Further, the induction coil is smaller in size than the diameter of the semiconductor substrate, so that the manufacturing apparatus of the semiconductor integrated circuit of the present invention can be downsized.

In addition to the above arrangement, in the manufacturing apparatus of the semiconductor integrated circuit of the present invention, it is preferable that the high-frequency power source can vary an amplitude and a frequency of an alternating current to be supplied.

According to the above arrangement, it is possible to vary the vibration of the semiconductor substrate, that is, the amplitude of the vibration and the vibration frequency. That is, the vibration varies in accordance with the amplitude and the current frequency of the alternating current. Therefore, under various electrolytic plating conditions, it is possible to more sufficiently vibrate a micro-region where the electrochemical double layers are positioned.

In order to achieve the above object, a manufacturing method of a semiconductor integrated circuit, includes the steps of:

supplying a plating liquid to a target plating surface of a semiconductor substrate; and

providing a bump electrode on the target plating surface by electrolytic plating method while vibrating the semiconductor substrate up and down.

In the electrolytic plating method, caused is a reaction of forming metallic ions making up the plating liquid into metal (for example, Au⁺+e⁻→Au; ion transport) on the above target plating surface, so that deposition of this metal forms the bump electrode.

The ion transport occurs in a minute region (micro-region), which is a thin part (several tens of Å thick) above the target plating surface, where electrochemical double layers are positioned.

The manufacturing method of the semiconductor integrated circuit of the present invention can form a bump electrode while vibrating the semiconductor substrate up and down. That is, a part for forming the bump electrode (a bump forming section) can be vibrated up and down. Therefore, it is possible to sufficiently agitate the plating liquid for reaching the bump forming section in the foregoing micro-region. This allows active ion transport at the bump forming section, so that it is possible to form a bump electrode having a uniform height. That is, it is possible to manufacture a semiconductor integrated circuit having a bump electrode uniform in height.

Further, the manufacturing method of the semiconductor integrated circuit of the present invention can sufficiently agitate the plating liquid without using the conventional apparatus which is provided with plural nozzles or plating liquid agitator sections. More specifically, the manufacturing method of the semiconductor integrated circuit of the present invention causes no differences in flow of the plating liquid caused by the plural nozzles, and no micro-bubbles produced by the plating liquid agitator section, both of which are causes of a bump electrode with non-uniform height in the conventional manufacturing method of the semiconductor integrated circuit (conventional method).

Up-and-down vibrations of the semiconductor substrate allow agitation of the plating liquid in the direction of thickness of the electrochemical double layers. Therefore, it is possible to effectively prevent a rate-limiting of reaction by the ion transport, as compared with vibrations in the lateral direction (left-and-right direction).

In order to achieve the above object, a manufacturing method of a semiconductor integrated circuit of the present invention, includes the steps of:

supplying a plating liquid to a target plating surface of a semiconductor substrate; and

providing a bump electrode on the target plating surface by electrolytic plating method while vibrating the semiconductor substrate through electromagnetic force.

According to the above arrangement, the manufacturing method of the semiconductor integrated circuit of the present invention can form the bump electrode while vibrating the semiconductor substrate up and down. That is, a part for forming the bump electrode (a bump forming section) can be vibrated up and down. Therefore, it is possible to sufficiently agitate the plating liquid for reaching the bump forming section in the foregoing micro-region. This allows active ion transport at the bump forming section, so that it is possible to form a bump electrode having a uniform height. That is, it is possible to manufacture a semiconductor integrated circuit having a bump electrode uniform in height.

Further, the manufacturing method of the semiconductor integrated circuit of the present invention can sufficiently agitate the plating liquid without using the conventional apparatus which is provided with plural nozzles or plating liquid agitator sections. More specifically, the manufacturing method of the semiconductor integrated circuit of the present invention causes no differences in flow of the plating liquid caused by the plural nozzles, and no micro-bubbles produced by the plating liquid agitator section, both of which are causes of a bump electrode with non-uniform height in the conventional method.

Further, in case where the semiconductor substrate is caused to vibrate using the electromagnetic force in such a manner, it is easy to optimize an amplitude and a cycle in the field of the electromagnetic force (electric field) and unnecessary to provide a moving part for vibrating the semiconductor substrate separately, so that it is possible to suppress the occurrence of malfunctions and troubles of the manufacturing apparatus itself.

In addition to the above arrangement, in the manufacturing method of the semiconductor integrated circuit of the present invention, it is preferable that the semiconductor substrate is caused to vibrate through electromagnetic force, which is produced through supply of a high-frequency current to an induction coil.

According to the above arrangement, only simple equipments, the induction coils and the high-frequency power source, can produce the magnetic field caused by the induction coils and electromagnetic force caused by the current passing through the target plating surface, so as to vibrate the semiconductor substrate through the electromagnetic force.

Further, it is preferable that the semiconductor integrated circuit of the present invention is manufactured by the above manufacturing method of the semiconductor integrated circuit.

According to the above arrangement, the semiconductor integrated circuit is manufactured while the semiconductor substrate is vibrated up and down. This provides a semiconductor integrated circuit having a bump electrode uniform in height.

The invention being thus described, it will be obvious that the same may be varied in many ways. Such variations are not to be regarded as a departure from the spirit and scope of the invention, and all such modifications as would be obvious to one skilled in the art intended to be included within the scope of the following claims.

What is claimed is:

1. A manufacturing apparatus of a semiconductor integrated circuit, which passes a current through a target plating surface of a semiconductor substrate, provided on a plating liquid, so as to provide a bump electrode on the semiconductor substrate by electrolytic plating method,
the manufacturing apparatus comprising:
a positive electrode which is provided in a tank section for storing the plating liquid;
a negative electrode which is connected to the target plating surface of the semiconductor substrate; and
substrate vibrating means for causing the semiconductor substrate to vibrate up and down when the bump electrode is provided.

2. The manufacturing apparatus of the semiconductor integrated circuit according to claim 1, wherein the semiconductor substrate vibrates at an audio frequency.

3. The manufacturing apparatus of the semiconductor integrated circuit according to claim 1, wherein the substrate vibrating means include:
an induction coil for causing the semiconductor substrate to vibrate through electromagnetic force; and
a high-frequency power source for supplying a high-frequency current to the induction coil.

4. The manufacturing apparatus of the semiconductor integrated circuit according to claim 3, wherein the induction coil is provided outside the tank section.

5. The manufacturing apparatus of the semiconductor integrated circuit according to claim 3, wherein the induction coil is provided at a predetermined distance away from other surface of the semiconductor substrate, which is on an opposite side of the tank section.

6. The manufacturing apparatus of the semiconductor integrated circuit according to claim 3, wherein the high-frequency power source can vary an amplitude and a frequency of an alternating current to be supplied.

7. A manufacturing apparatus of a semiconductor integrated circuit, which passes a current through a target plating surface of a semiconductor substrate, provided on a plating liquid, so as to provide a bump electrode on the semiconductor substrate by electrolytic plating method,
the manufacturing apparatus comprising:
a positive electrode which is provided in a tank section for storing the plating liquid;
a negative electrode which is connected to the target plating surface of the semiconductor substrate; and
substrate vibrating means for causing the semiconductor substrate to vibrate up and down when the bump electrode is provided, the substrate vibrating means including:
a plurality of induction coils for causing the semiconductor substrate to vibrate through electromagnetic force, each of the induction coils being smaller in size than the semiconductor substrate; and
a high-frequency power source for supplying a high-frequency current to the induction coils.

8. A manufacturing apparatus of a semiconductor integrated circuit, which passes a current through a target plating surface of a semiconductor substrate, provided on a plating liquid, so as to provide a bump electrode on the semiconductor substrate by electrolytic plating method,
the manufacturing apparatus comprising:
a positive electrode which is provided in a tank section for storing the plating liquid;
a negative electrode which is connected to the target plating surface of the semiconductor substrate;
an induction coil for causing the semiconductor substrate to vibrate through electromagnetic force; and
a high-frequency power source for supplying a high-frequency current to the induction coil.

9. The manufacturing apparatus of the semiconductor integrated circuit according to claim 8, wherein the semiconductor substrate vibrates at an audio frequency.

10. The manufacturing apparatus of the semiconductor integrated circuit according to claim 8, wherein the induction coil is provided outside the tank section.

11. The manufacturing apparatus of the semiconductor integrated circuit according to claim 8, wherein the induction coil is provided at a predetermined distance away from other surface of the semiconductor substrate, which is on an opposite side of the tank section.

12. The manufacturing apparatus of the semiconductor integrated circuit according to claim 8, wherein the high-frequency power source can vary an amplitude and a frequency of an alternating current to be supplied.

13. A manufacturing apparatus of a semiconductor integrated circuit, which passes a current through a target plating surface of a semiconductor substrate, provided on a plating liquid, so as to provide a bump electrode on the semiconductor substrate by electrolytic plating method,
the manufacturing apparatus comprising:
a positive electrode which is provided in a tank section for storing the plating liquid;
a negative electrode which is connected to the target plating surface of the semiconductor substrate;
a plurality of induction coils for causing the semiconductor substrate to vibrate through electromagnetic force, each of the induction coils being smaller in size than the semiconductor substrate; and
a high-frequency power source for supplying a high-frequency current to the induction coils.

14. A manufacturing method of a semiconductor integrated circuit, comprising the steps of:
supplying a plating liquid to a target plating surface of a semiconductor substrate; and
providing a bump electrode on the target plating surface by electrolytic plating method while vibrating the semiconductor substrate up and down.

15. The manufacturing method of the semiconductor integrated circuit according to claim 14, wherein the semiconductor substrate vibrates at an audio frequency.

16. The manufacturing method of the semiconductor integrated circuit according to claim 14, wherein the semiconductor substrate is caused to vibrate through electromagnetic force, which is produced through supply of a high-frequency current to an induction coil.

17. A manufacturing method of a semiconductor integrated circuit, comprising the steps of:
supplying a plating liquid to a target plating surface of a semiconductor substrate; and
providing a bump electrode on the target plating surface by electrolytic plating method while vibrating the semiconductor substrate through electromagnetic force.

18. The manufacturing method of the semiconductor integrated circuit according to claim 17, wherein the semiconductor substrate vibrates at an audio frequency.

19. The manufacturing method of the semiconductor integrated circuit according to claim 17, wherein the semiconductor substrate is caused to vibrate through the electromagnetic force, which is produced through supply of a high-frequency current to an induction coil.

20. A semiconductor integrated circuit which is manufactured by a manufacturing method of a semiconductor integrated circuit,
the manufacturing method including the steps of:
supplying a plating liquid to a target plating surface of a semiconductor substrate; and
providing a bump electrode on the target plating surface by electrolytic plating method while vibrating the semiconductor substrate up and down.

21. A semiconductor integrated circuit which is manufactured by a manufacturing method of a semiconductor integrated circuit,
the manufacturing method including the steps of:
supplying a plating liquid to a target plating surface of a semiconductor substrate; and
providing a bump electrode on the target plating surface by electrolytic plating method while vibrating the semiconductor substrate through electromagnetic force.

22. A semiconductor integrated circuit according to claim 21, wherein the semiconductor substrate is caused to vibrate through the electromagnetic force, which is produced through supply of a high-frequency current to an induction coil.

23. A semiconductor integrated circuit which is manufactured by a manufacturing apparatus of a semiconductor integrated circuit, which passes a current through a target plating surface of a semiconductor substrate, provided on a plating liquid, so as to provide a bump electrode on the semiconductor substrate by electrolytic plating method,
the manufacturing apparatus comprising:
a positive electrode which is provided in a tank section for storing the plating liquid;
a negative electrode which is connected to the target plating surface of the semiconductor substrate; and
substrate vibrating means for causing the semiconductor substrate to vibrate up and down.

24. A semiconductor integrated circuit which is manufactured by a manufacturing apparatus of a semiconductor integrated circuit, which passes a current through a target plating surface of a semiconductor substrate, provided on a plating liquid, so as to provide a bump electrode on the semiconductor substrate by electrolytic plating method,
the manufacturing apparatus comprising:
a positive electrode which is provided in a tank section for storing the plating liquid;
a negative electrode which is connected to the target plating surface of the semiconductor substrate;
an induction coil for causing the semiconductor substrate to vibrate through electromagnetic force; and
a high-frequency power source for supplying a high-frequency current to the induction coil.
